(19) United States
(12) Patent Application Publication
(10) Pub. No.: US 2016/0161568 A1
(43) Pub. Date: Jun. 9, 2016

(54) Identification of a Unique Attribute of a Power Adapter Based on an Adjust Pin

(71) Applicant: HEWLETT-PACKARD DEVELOPMENT COMPANY, L.P., Houston, TX (US)

(72) Inventor: THOMAS SAWYERS, HOUSTON, TX (US)

(21) Appl. No.: 14/897,997

(22) PCT Filed: Aug. 30, 2013
(86) PCT No.: PCT/US2013/057662

§ 371 Date: Dec. 11, 2015

(51) Int. Cl. G01R 31/40; G05B 24/02

(52) U.S. Cl. CPC G01R 31/40; G05B 24/02

(57) ABSTRACT

Examples disclose a power system comprising a powered circuit to measure a voltage from an adjust pin associated with a power adapter. The voltage indicates a unique attribute of the power adapter. The power system also comprises a controller to identify the unique attribute of the power adapter based on the voltage.

### BACKGROUND

Power adapters may be used to convert one form of electrical energy into another. For example, the power adapter may include an alternating current (AC) adapter to convert alternating current from a power outlet into direct current to operate an external computing device.

### BRIEF DESCRIPTION OF THE DRAWINGS

In the accompanying drawings, like numerals refer to like components or blocks. The following detailed description references the drawings, wherein:

FIG. 1 is a block diagram of an example power adapter to transmit a voltage on an adjust pin to a powered circuit, the powered circuit including a controller to identify a unique attribute of the power adapter corresponding to the voltage;

FIG. 2A is an example circuit diagram of an alternating current (AC) adapter and a powered circuit, the powered circuit receives a voltage on a voltage adjust pin which may be utilized to adjust an output voltage to the powered circuit;

FIG. 2B is an example data table of various ratings of a voltage from a voltage adjust pin, the various ratings of the voltage each correspond to a unique power rating of an AC adapter;

FIG. 3 is a flowchart of an example method to receive an identifier indicating a unique power rating of an AC adapter and to identify the unique power rating;

FIG. 4 is a flowchart of an example method to receive an identifier which indicates a unique power rating of an AC adapter, the identifier includes a voltage form a voltage adjust pin, and identifying the unique power rating by converting the identifier to a digital identifier and utilizing a table; and

FIG. 5 is a block diagram of an example computing device with a processor to execute instructions in a machine-readable storage medium for receiving an adjust pin voltage, processing the adjust pin voltage according to a table, and identifying a unique attribute of an AC adapter, accordingly.

### DETAILED DESCRIPTION

Computing devices may utilize a power adapter, such as an AC adapter to charge a battery so the computing device may function, However, these power adapters may not be interchangeable between computing devices as the adapter's power rating must be rated to that of the computing device. Additionally, identifying the adapter's power rating may involve an additional dedicated identification pin which may not be feasible as the additional pin may increase real estate.

To address these issues, examples disclosed herein provide a method to receive an identifier from an adjust pin associated with an AC adapter. The adjust pin associated with the AC adapter may be utilized to adjust an output voltage of the AC adapter and to communicate an identifier for a load to utilize to determine a power rating. The identifier may include an internal characteristic in which the load may identify a particular AC adapter among a series of AC adapters. For example, the identifier may include a value of a resistor divider within the AC adapter and/or a unique voltage from the adjust pin. The unique voltage is an identifying voltage in which the load may identify that particular AC adapter among the series of AC adapters. This implementation enables a computing device including the powered circuit to identify the unique power rating of a given alternating current (AC) adapter in the series of different power rated AC adapters, Further, allowing the load to identify the type of unique power rating from the adjust pin of the AC adapter enables the adjust pin to be utilized for multiple functions (e.g., adjusting an output voltage to the load and identifying the unique power rating from the measured voltage). This reduces a number of pins between the AC adapter and the load and reducing the overall real estate.

Additionally, using the identifier of the AC adapter measured from the adjust pin provides an internal characteristic of the AC adapter to determine the unique power rating. Determining the unique power rating of the AC adapter, enables the load (e.g., computing device) to intelligently determine the unique power rating of the AC adapter so the load may take appropriate measures. For example, if the unique power rating of the AC adapter is higher than needed to charge a battery within the load, the load may adjust the unique power rating internally to a power rated for the load. Further, for the series of AC adapters, the identifier or internal characteristic of a particular AC adapter communicates to the load the unique attribute (e.g., unique power rating) of that particular AC adapter.

In another example, the series of AC adapters may include a resistor of fixed value, while each AC adapter includes a different set of values for a resistor divider. Each set of values for a resistor divider corresponds to the identification voltage. This enables the load to identify the unique power rating corresponding to the voltage measurement.

In a further example, the AC adapter may include a common connector among the series of AC adapters. In this example, the connector includes the adjust pin, an output voltage pin to deliver output voltage to the load, and a ground pin. Further in this example, the series of AC adapters may utilize the common connector despite each AC adapter having a different identifying voltage (i.e., different unique voltage) measured on the adjust pin. Further, the series of AC adapters may utilize the common connector despite each AC adapter having a different unique power rating.

In summary, examples disclosed herein enable a computing device to identify a unique power rating of an AC adapter based on a voltage measured at an adjust pin associated with the AC adapter. Additionally, identifying the unique power rating from the adjust pin enables the pin to be utilized for multiple functions, thus reducing a number of pins between the AC adapter and a load.

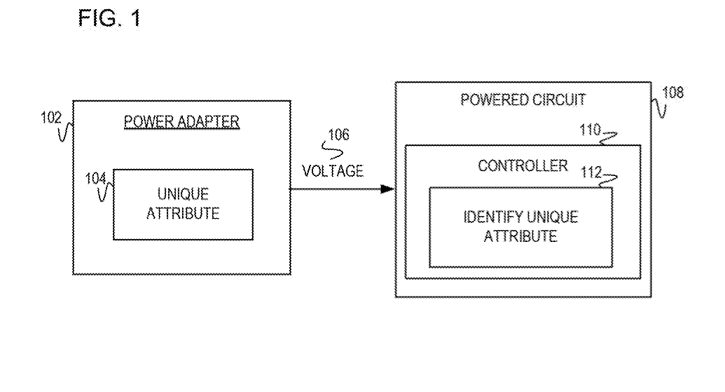

Referring now to the figures, FIG. 1 is a block diagram of an example power adapter 102 to transmit a voltage 106 on an adjust pin to a powered circuit 108. The voltage 106 indicates to the powered circuit 108, a unique attribute 104 of the power adapter 102. A controller 110 associated with the powered circuit 108 identifies the unique attribute 104 of the power adapter 102 at module 112. Identifying the unique attribute 104 measured from the adjust pin of the power adapter 102, the powered circuit 108 distinguishes the power adapter 102 among a series of power adapters. For example, for a series of AC adapters each AC adapter may correspond to a different power rating, thus a unique voltage may be measured at the adjust pin of the given AC adapter to identify a power rating of the given AC adapter. The unique voltage is an identification voltage in which the powered circuit 108 identifies the power adapter 102 through determining the unique attribute 104 based on the identification voltage. FIG. 1 illustrates a power system including the power adapter 102 and the powered circuit 108, as such, implementations of the power system include a computing system, networking system, or other type of system in which provides power to the load from the power adapter 102. Additionally, although FIG. 1 illustrates the power system as including the power adapter 102 and the powered circuit 108, implementations should not be limited as this was done for illustration purposes. For example, the powered circuit 108 may be part of a computing device which receives power through the power adapter 102.

The power adapter 102 is an external power supply that powers the load when the load is plugged into the power adapter 102. In one implementation, the power adapter 102 may include an AC adapter as illustrated in later figures. The power adapter 102 is used to supply output voltage (not illustrated) to the load to power the load. Additionally, the power adapter 102 may receive its input power from an external source (not illustrated) to supply the output voltage to the load. In another implementation, the power adapter 102 includes a resistor fixed value and a resistor divider (e.g., voltage divider) of various values that correspond to the unique voltage on the adjust pin to the powered circuit 108. In another implementation, the power adapter 102 includes a common connector among the series of power adapters to the load. In this implementation, the connector includes the adjust pin, an output voltage pin, and a ground pin. Further in this implementation, the series of power adapters may utilize the common connector despite each power adapter having a different voltage on the adjust pin and thus each power adapter having a different unique power rating. The series of power adapters may have a common voltage on the output voltage pin, despite each power adapter having a different voltage on the adjust pin and thus each power adapter having a different unique power rating.

The unique attribute 104 is a property of the power adapter 102 used to identify the given power adapter among the series (e.g., family) of power adapters to the load. For example, the unique attribute 104 may include a property, characteristic, or other type of identifier of the power adapter 102. For example, each AC adapter member within the family of AC adapters corresponds to a different power rating, thus each power rating is unique to that AC adapter member. In one implementation, the unique attribute 104 includes the unique power rating of a given power adapter 102. In this implementation, for the series of power adapters, each power adapter may have a different unique power rating, thus measuring the unique voltage on the adjust pin, the load identifies the unique power rating of the given power adapter.

The voltage 106 is an electrical potential difference from the adjust pin to the ground pin and represents the unique voltage (i.e., identifying voltage) measured by the powered circuit 108 from the adjust pin to the ground pin on the power adapter 102. In another implementation, the voltage 106 may include a unique identifier of the power adapter 102. The voltage 106 and/or unique identifier of the power adapter 102 are internal characteristics of the power adapter 102 to distinguish it from the series of power adapters. The adjust pin is associated with power adapter 102 as providing the voltage 106 to uniquely identify the given power adapter. The adjust pin may also be referred to as the voltage adjust pin throughout the document as each of these pins may be utilized to adjust the voltage of an output voltage pin and identify the power adapter 102. This enables the adjust pin to be utilized for multiple functions, such as adjusting the output voltage to the load and for identifying the unique attribute 104 of the power adapter 102, thus reducing a number of pins between the power adapter 102 and the load. In a further implementation, the voltage 106 may include an adjust pin voltage. This implementation is discussed in detail in a later figure.

The powered circuit 108 is part of the load which receives an output voltage (not illustrated) to power various functions of the load. The load may be an electronic device that includes the powered circuit 108 to harness output power from the power adapter 102 to charge a battery (not illustrated) for operating the load. As such, implementations of the load may include a portable device, computing device, tablet, electronic device, mobile device, client device, personal computer, laptop, game console, or other type of electronic device capable of receiving voltage 106 on the adjust pin from the power adapter 102 and in turn, identifying the unique attribute of the power adapter 102. For example, using the voltage 106 as uniquely identifying a type of AC adapter 102 from the voltage adjust pin, the load determines the unique power rating of the AC adapter enables the load to intelligently determine the power rating of the AC adapter so the load may take appropriate measures. For the series or family of power adapters, the internal characteristic communicates to the load the unique attribute 104 (e.g., unique power rating) of that particular power adapter. In another implementation, the powered circuit 108 is part of a charging control circuit to charge a battery in the load.

The controller 110 is part of the powered circuit 108 and the load to identify the unique attribute 104 of the power adapter 102 at module 112. In one implementation, the voltage 106 received by the powered circuit 108 is converted to a digital signal as input to the controller 110. In this implementation, the digital signal includes a digital value corresponding to a magnitude of the voltage 106 on the adjust pin. Implementations of the controller 110 include a microchip, processor, chipset, electronic circuit, microprocessor, semiconductor, microcontroller, central processing unit (CPU), graphics processing unit (GPU), or other programmable device capable of executing module 112.

At module 112, the controller 110 identifies the unique attribute 104 of the power adapter 102. In one implementation, the unique attribute 104 of the power adapter 102 includes the unique power rating. In this implementation, each power adapter in a series of power adapters includes a unique voltage (i.e., identifying voltage) corresponding to the unique power rating. The controller 110 measures the unique voltage at the adjust pin. The controller 110 may then identify the corresponding unique power rating based on the unique voltage at the adjust pin. In another implementation, the controller 110 utilizes a table to identify the unique attribute 104. The table is means of data information for the controller 110 to reference for identifying the unique attribute 104 based on the voltage 106 from the adjust pin of the power adapter 102. The table may include data elements such as the voltage corresponding on the adjust pin, the various resistor values of the resistor divider in the power adapter 102, and the unique power rating corresponding to these data elements. In this implementation, the controller 110 may access the table to reference the unique voltage received on the adjust pin and identify the corresponding unique power rating for the given power adapter. In a further implementation, upon measure the voltage 106 from the adjust pin, if the voltage 106 is above or below a threshold voltage, this could indicate whether the power rating of the power adapter 102 is above or below a threshold power rating. These implementations are discussed in detail in a later figure. Implementations of the module 112 include a set of instructions, process, operation, logic, algorithm, technique, logical function, firmware, and or software executable by the controller 110 to identify the unique attribute 104 of the power adapter 102.

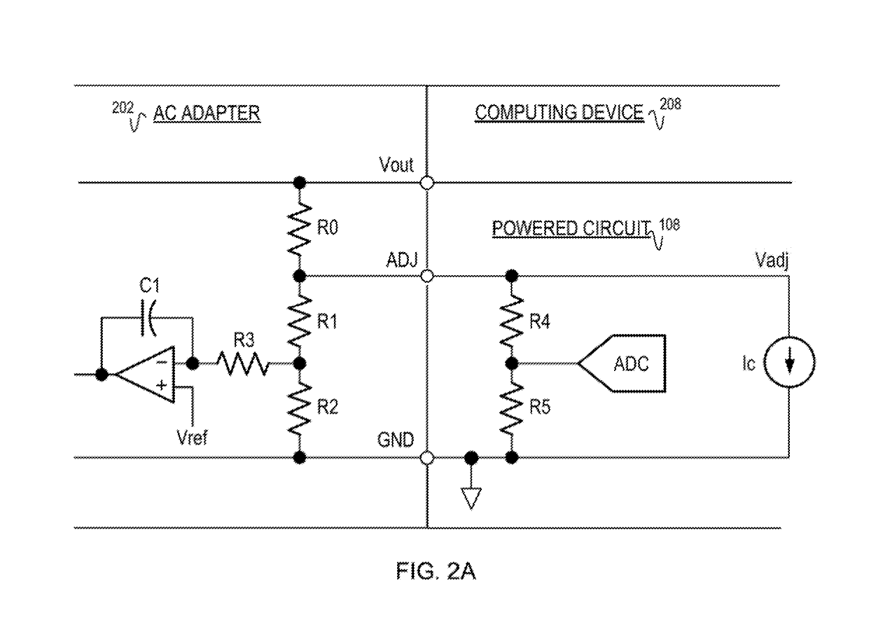

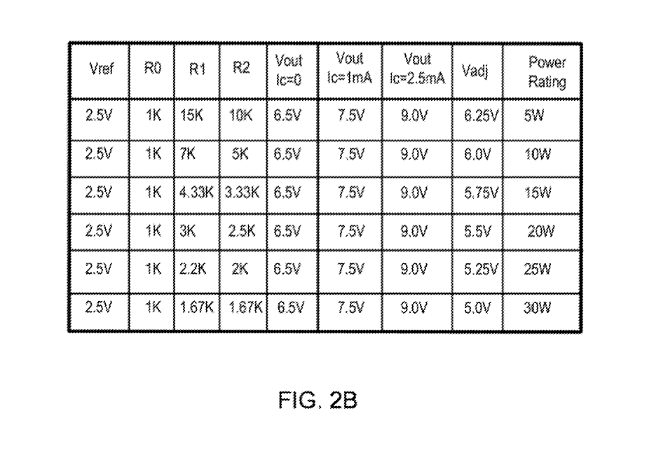

FIG. 2A is an example circuit diagram of an alternating current (AC) adapter 202 and a computing device 208 including a powered circuit 108. The computing device 208 receives an output voltage (Vout) from the AC adapter 202, a voltage (Vadj) from a voltage adjust pin (ADJ), and ground (GND). The voltage adjust pin (ADJ) may be utilized to adjust the output voltage (Vout) to the computing device 208. The computing device 208 is part of a load which interfaces with the AC adapter 202 to receive the output voltage (Vout) to power itself. In one implementation, the AC adapter 202 includes a common connector among a series of AC adapters. In this implementation, the connector includes a ground pin (GND), the voltage adjust pin (ADJ), and an output voltage pin (Vout) to interface between the AC adapter 202 and the computing device 208. Further, in this implementation, the series of AC adapters may utilize the common connector despite each AC adapter having a unique voltage (Vadj) measured on the voltage adjust pin (ADJ). Each AC adapter includes the unique voltage (Vadj) for the powered circuit 108 to identify a unique power rating of the AC adapter 202 corresponding to that unique voltage (Vadj). The unique voltage (Vadj) may also be referred to as the voltage throughout the document.

In one implementation, the voltage (Vadj) measured from the voltage adjust pin (ADJ) and determine whether the voltage (Vadj) is above or below a voltage threshold. Based on whether the voltage (Vadj) is above or below the voltage threshold, indicates whether the power rating is above or below a threshold power rating. For example, if the voltage threshold is 5.8 volts, if the voltage (Vadj) is above this threshold indicates the power rating is below 15 watts. If the voltage (Vadj) is below the threshold voltage of 5.8 volts indicates the power rating is above 15 watts. This uses a comparison of the threshold voltage to the voltage (Vadj) that may be determined by a comparator associated with the load without the use of firmware and associated coding.

The AC adapter 202 delivers output voltage (Vout) to the computing device 208 and includes the voltage adjust pin (ADJ) for the powered circuit 108 to measure the voltage (Vadj) to identify the unique power rating of the AC adapter 202. The AC adapter 202 includes a fixed value resistor (R0) between the output voltage pin and the voltage adjust pin (ADJ). Additionally, the AC adapter 202 includes a resistor divider of multiple resistors (R1 and R2). These resistors (R1 and R2) may have various values of resistance on each resistor (R1 and R2) to correspond to the unique voltage (Vadj). The AC adapter 202 includes an op-amp with an input resistor (R3), a capacitor (C1) and a reference voltage (Vref) to operate as an error amplifier to actively regulate the output voltage (Vout). For a given AC adapter 202, the voltage (Vadj) is regulated to a constant value through action of the op-amp with the resistors (R1 and R2).

The powered circuit 108 receives the voltage (Vadj) from the voltage adjust pin (ADJ) associated with the AC adapter 202. An analog to digital converter (ADC) may convert the voltage (Vadj) into a digital value for input to a controller. The controller may use this digital value to identify the corresponding power rating of the AC adapter 202 according to a table. An example table is explained in detail in FIG. 2B. The powered circuit 108 may include multiple resistors (R4 and R5) to sample the voltage (Vadj) from the voltage adjust pin (ADJ) into the ADC. These resistors (R4 and R5) may provide protection to the computing device 208 if the voltage (Vadj) is shorted to the output voltage (Vout). Additionally, these resistors (R4 and R5) may also scale the voltage (Vadj) to a magnitude which may be read by the controller (not illustrated). Further, the powered circuit 108 includes a control current (Ic) to adjust the output voltage (Vout). The control current (Ic) flows through the resistor of fixed value (R0) creating an increased voltage across R0. This increases the output voltage (Vout) as the output voltage (Vout) equals the voltage (Vadj) and the voltage drop across the resistor of fixed value (R0), thus if the current adjusts the voltage drop across the resistor of fixed value (R0), this in turn adjusts the output voltage (Vout).

The computing device 208 may receive an output voltage (Vout) to charge a battery (not illustrated) useable for powering the computing device 208. The powered circuit 108 receives a voltage (Vadj) which represents a unique voltage corresponding to a given AC adapter among a series of AC adapters. The powered circuit 108 measures the voltage (Vadj) from the voltage adjust pin (ADJ) to identify a unique power rating based on the voltage (Vadj). In one implementation, the powered circuit 108 includes a controller to reference the voltage (Vadj) to identify the unique power rating of the given AC adapter. The powered circuit 108 includes a control current (Ic) to regulate the output voltage (Vout) through adjusting the current drawn from the voltage adjust pin (ADJ).

FIG. 2B represents an example data table of various ratings corresponding to a unique power rating of an AC adapter. The series of AC adapters may include various power ratings from 5 watts to 30 watts. Each row in the table may represent the values corresponding to a specific AC adapter, while each column may represent the various values for a particular element (Vref, R0, R1, R2, Vout, Vadj, Power Rating) associated with the series of AC adapters. The data table in FIG. 28 corresponds to the particular elements illustrated in FIG. 2A. Additionally, resistors (R4 and R5) play no role in the table as FIG. 2B assumes that the sum of the values of resistors (R4 and R5) in the powered circuit 108 is much greater than that of the resistors (R1 and R2) in the AC adapter 202. In other words, it is assumed R4+R5>>R1+R2.

The table may be referenced by a controller associated with a powered circuit 108 to identify a unique power rating (Power Rating) of the AC adapter 202. In the table a reference voltage (Vref) used as input to an op-amp within the AC adapter 202 remains constant. A fixed value resistor (R0) is within the AC adapter 202 between an output voltage (Vout) and a voltage (Vadj) on the voltage adjust pin (ADJ). A voltage divider including resistors (R1 and R2) may vary in values depending on the desired voltage (Vadj) on the voltage adjust pin (ADJ). Additionally, an output voltage (Vout) may adjust between 6.5 volts to 9.0 volts based on whether a control current (Ic) within a powered circuit 108 is drawing current between 0 amps to 2.5 milliamps. For example, when the control current (Ic) is drawing around 1 milliamp, the output voltage (Vout) is around 7.5 volts.

FIG. 28 illustrates the unique voltages (Vadj) measured from the voltage adjust pin (ADJ) and the corresponding unique power rating of a given AC adapter among a series of AC adapters. For example, the series of AC adapters includes power ratings from 5 watts to 30 watts, thus to identify the given power rating of a particular AC adapter, the table may be referenced according to the unique voltage (Vadj) on the voltage adjust pin (ADJ).

The resistor divider (R1 and R2) includes various values of resistance to achieve the unique voltage (Vadj) measurement by the powered circuit 108. For example, the resistor divider may include resistance values of 3 kilohms and 2.5 kilohms, respectively, and a reference voltage (Vref) of 2.5 Volts. In this example, the unique voltage (Vadj) may include 5.5 volts which the controller may reference to obtain the unique power rating of 20 watts. Additionally, the series of AC adapters may each include a different value of the voltage divider (R1 and R2), such that the series of AC adapters each may include a different unique voltage (Vadj) at the voltage adjust pin, yet the series of AC adapters may include a common reference voltage (Vref) and a common output voltage (Vout).

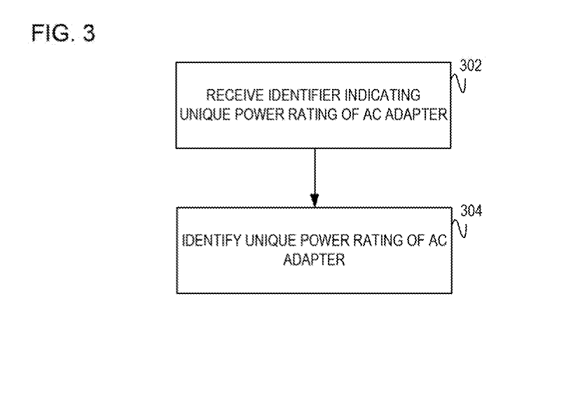

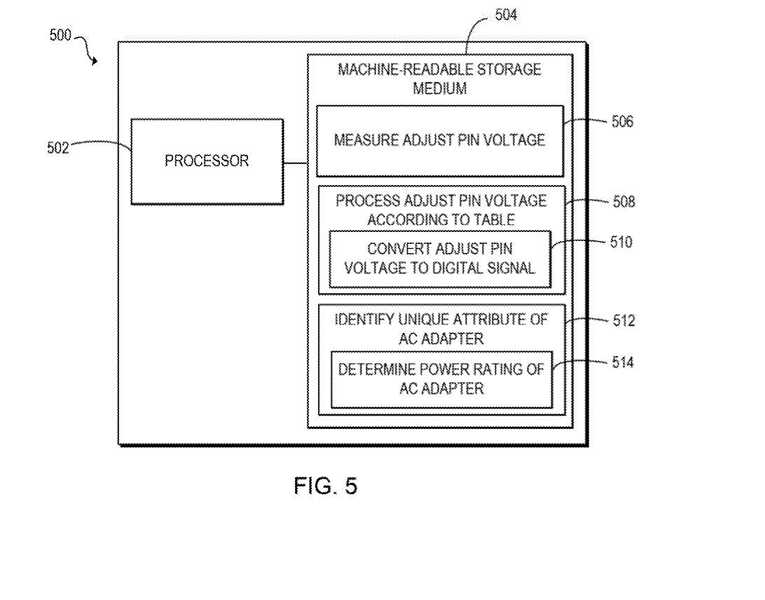

FIG. 3 is a flowchart of an example method to receive an identifier from a voltage adjust pin associated with an alternating current (AC) adapter. The identifier indicates a unique power rating of the AC adapter, so the method identifies the unique power rating of the AC adapter. The identifier may include a voltage from the voltage adjust pin for a controller associated with a powered circuit to identify the unique power rating of the AC adapter. The method enables a load including the powered circuit to identify the unique power rating of the AC adapter which may be a member in a family of different power rated AC adapters. Further, allowing the load to identify the type of unique power rating from the voltage adjust pin of the AC adapter enables the voltage adjust pin to be utilized for multiple functions (e.g., adjusting an output voltage to the load and identifying the unique power rating from the received voltage). This reduces a number of pins between the AC adapter and the load, by not requiring separate pins for adjust and ID, and reduces the overall real estate. Once identifying the unique power rating of the AC adapter, the load may ready itself for harnessing the unique power rating to remain operational even though the power rating may be higher or lower than a rated power of the load. In discussing FIG. 3, references may be made to the components in FIGS. 1-2B to provide contextual examples. Further, although FIG. 3 is described as implemented by a powered circuit 108 as in FIG. 1, it may be executed on other suitable components. For example, FIG. 3 may be implemented in the form of executable instructions on a machine readable storage medium, such as machine-readable storage medium 504 as in FIG. 5.

At operation 302, the powered circuit may receive the identifier from the voltage adjust pin. The identifier indicates to the controller associated with the powered circuit, the unique power rating of the AC adapter. The identifier includes the voltage transmitted on the voltage adjust pin associated with the AC adapter. In this implementation, the AC adapter includes a resistor of fixed value and a voltage divider of multiple resistors which vary in value. The variances in values correspond to different values of the voltage received by the powered circuit. In this manner, each AC adapter member of the family may include the resistor of fixed value, but different values of the multiple resistors in a voltage divider. The different values of the multiple resistors may result in different voltages on the voltage adjust pin, each different voltage indicating a different unique power rating of its respective AC adapter. In this implementation, a family of resistor dividers may maintain a desired output voltage to the load, where each AC adapter member of the family may include a different unique voltage at the voltage adjust pin, yet the desired output voltage remains unchanged. The unique voltage is measured at the voltage adjust pin, wherein each unique voltage at the adjust voltage pin is assigned to a corresponding power rating. For example, the series of AC adapters (e.g., family of AC adapters) may be designed to have a nominal output voltage of 6.5 volts which is adjustable up to 9.0 volts by a control current drawn from the voltage adjust pin. In this example, one of the AC adapters may be designed for a rated power of 5 W, thus each 5 W AC adapter may be designed to operate with the voltage at the voltage adjust pin of 6.25 volts. In a further example, another member of the AC adapter series may be rated for 10 W, thus each 10 W AC adapter may be designed to operate with 6.0 volts at the voltage adjust pin. Each of the voltages measured at the voltage adjust pin correspond to the unique power rating of each AC adapter within the AC adapter series. Thus, each of the AC adapters may include different values in the resistor divider which in turn affects the voltage measured at the voltage adjust pin by the load. The load (e.g., powered circuit) may identify the unique power rating from measuring the voltage at the voltage adjust pin at operation 304. In a further implementation, the identifier may include the values of the resistor divider to identify the corresponding unique power rating of each AC adapter at operation 304.

At operation 304, the controller associated with the powered circuit identifies the unique power rating of the AC adapter based on the received identifier at operation 302. In one implementation, the controller may use the identifier received at operation 302 to identify the unique attribute of the AC adapter. The unique attribute is a means of identifying the particular AC adapter among the series of AC adapters. For example, the unique attribute may include a property, characteristic, or other type of identifier of the AC adapter. In another implementation, the controller may include a table or other type of data information to determine the unique power rating based on the identifier received at operation 302. The table is a means of storing data information regarding the AC adapter for the controller to reference for identifying the unique attribute of the AC adapter. The table may include data elements such as the voltage corresponding on the voltage adjust pin, the various resistor values of the voltage divider in the AC adapter, and the unique power rating corresponding to these data elements. In this implementation, the controller may access the table, lookup the voltage data and identify the corresponding unique power rating for a particular AC adapter. In another implementation, the identifier received at operation 302 may be converted to a digital identifier for input to the controller to identify the unique power rating of the AC adapter.

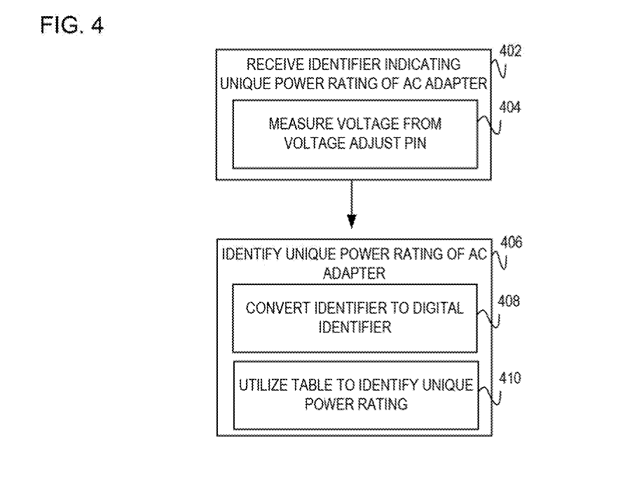

FIG. 4 is a flowchart of an example method to receive an identifier indicating a unique power rating of an alternating current (AC) adapter among a series of AC adapters. Each of the AC adapters among the series of AC adapters may include a unique value of a resistor divider and/or unique voltage at a voltage adjust pin from the AC adapter to the powered circuit. In one implementation, the identifier may include an analog signal, in the form of a voltage from the voltage adjust pin, in which a controller associated with the powered circuit may identify the unique power rating by converting the voltage to a digital signal. Using the digital signal, the controller may utilize a table to identify the unique power rating of a given AC adapter. In discussing FIG. 4, references may be made to the components in FIGS. 1-2B to provide contextual examples. Further, although FIG. 4 is described as implemented by a powered circuit 108 as in FIG. 1, it may be executed on other suitable components. For example, FIG. 4 may be implemented in the form of executable instructions on a machine readable storage medium, such as machine-readable storage medium 504 as in FIG. 5.

At operation 402, a powered circuit as part of a load, receives the identifier from a voltage adjust pin on the AC adapter. In one implementation, the identifier may include a value of a resistor divider within the AC adapter. In another implementation, the identifier may include a voltage from the voltage adjust pin. In this implementation, the load through means of a controller may measure the voltage from the voltage adjust pin. The identifier indicates to the powered circuit, the unique power rating of a given AC adapter in the series of AC adapters. Operation 402 may be similar in functionality to operation 302 as in FIG. 3.

At operation 404, the powered circuit as part of the load receives the voltage from the voltage adjust pin on the AC adapter. At this operation, the controller associated with the powered circuit may measure the voltage from the voltage adjust pin. The voltage adjust pin provides the identifier, such as the voltage, to the powered circuit for the controller to identify the corresponding unique power rating of the AC adapter. This enables the series of AC adapters to provide a nominal output voltage to the load, each AC adapter having a unique power rating as identified from the unique voltage at the voltage adjust pin. In this manner, the series of AC adapters may be rated for a common output voltage to the load, even though each of the AC adapters within the series of AC adapters may include a different unique voltage at the voltage adjust pin. In this implementation, each AC adapter may include a different value of a resistor divider (i.e., voltage divider) to provide the unique voltage at the voltage adjust pin for the powered circuit to measure. Further, this enables each AC adapter to be identified by the load in which they power.

At operation 406, the controller associated with the powered circuit and the load, identifies the unique power rating of the AC adapter. In one implementation, the identifier and/or the voltage received at operations 402-404 is converted to the digital identifier and/or the digital signal at operation 410. In an additional implementation, the identifier and/or the signal received at operations 402-404, respectively, are utilized in accordance to the table at operation 410 to determine the unique power rating. In a further implementation, the digital identifier and/or the digital signal converted at operation 408 is utilized in accordance with the table at operation 410 to determine the unique power rating. Operation 406 may be similar in functionality to operation 304 as in FIG. 3.

At operation 408, the identifier received at operation 402 is converted into the digital identifier. In another implementation, the voltage received from voltage adjust pin at operation 404 is converted into the digital signal. The powered circuit may include an analog-to-digital converter (ADC) to convert the received identifier and/or voltage at operations 402-404 into its digital value. The ADC is an electrical device that converts a physical quantity of voltage to a digital value that represents the quantity's magnitude. The digital value is used as input to the controller to then identify the unique power rating of a given AC adapter at operation 410.

At operation 410, the controller utilizes the table to identify the unique power rating of the given AC adapter. In one implementation, the digital value converted at operation 408 is used by the controller to identify the corresponding unique power rating. In another implementation, the identifier and/or voltage at operations 402-404 is used to identify the corresponding unique power rating of the given AC adapter.

FIG. 5 is a block diagram of an example computing device 500 with a processor 502 to execute instructions 506-514 within a machine-readable storage medium 504. Specifically, the computing device 500 with the processor 502 is to receive an adjust pin voltage, process the adjust pin voltage according to a table, and identify a unique power rating of an alternating current (AC) adapter, accordingly. Although the computing device 500 includes processor 502 and machine-readable storage medium 504, it may also include other components that would be suitable to one skilled in the art. For example, the computing device 500 may include the powered circuit 108 and/or controller 110 as in FIG. 1. The computing device 500 is an electronic device with the processor 502 capable of executing instructions 506-514, and as such embodiments of the computing device 500 include a mobile device, client device, personal computer, desktop computer, laptop, tablet, video game console, or other type of electronic device capable of executing instructions 506-514. The instructions 506-514 may be implemented as methods, functions, operations, and other processes implemented as machine-readable instructions stored on the storage medium 504, which may be n-transitory, such as hardware storage devices (e.g., random access memory (RAM), read only memory (ROM), erasable programmable ROM, electrically erasable ROM, hard drives, and flash memory).

The processor 502 may fetch, decode, and execute instructions 506-514 to receive the adjust pin voltage and identify the unique power rating of the AC adapter corresponding to the received voltage, accordingly. In one implementation, upon executing instructions 506-508, the process 502 may execute instruction 510 to convert the voltage to a digital signal and proceed to execute instructions 512-514. Specifically, the processor 502 executes instruction 506-514 to: receive the adjust pin voltage indicating a unique power rating of the AC adapter; process the received adjust pin voltage according to a table for identifying the unique power rating; convert the adjust pin voltage to a digital signal for input to the controller; identify the unique attribute of the AC adapter; and wherein the unique attribute includes the unique power rating of the AC adapter. Implementations of the processor 502 may include an integrated circuit, a microchip, processor, chipset, electronic circuit, microprocessor, semiconductor, microcontroller, central processing unit (CPU), graphics processing unit (GPU), semiconductor, or other type of programmable device capable of executing, instructions 506-514.

The machine-readable storage medium 504 includes instructions 506-514 for the processor 502 to fetch, decode, and execute. In another embodiment, the machine-readable storage medium 504 may be an electronic, magnetic, optical, memory, storage, flash-drive, or other physical device that contains or stores executable instructions. Thus, the machine-readable storage medium 504 may include, for example, Random Access Memory (RAM), an Electrically Erasable Programmable Read-Only Memory (EEPROM), a storage drive, a memory cache, network storage, a Compact Disc Read Only Memory (CDROM) and the like. As such, the machine-readable storage medium 504 may include an application and/or firmware which can be utilized independently and/or in conjunction with the processor 502 to fetch, decode, and/or execute instructions of the machine-readable storage medium 504. The application and/or firmware may be stored on the machine-readable storage medium 504 and/or stored on another location of the computing device 500.

In summary, examples disclosed herein enable a computing device to identify a unique power rating of an AC adapter based on a voltage measured at a voltage adjust pin associated with the AC adapter. Additionally, identifying the unique power rating from the voltage adjust pin enables the pin to be utilized for multiple functions, thus reducing a number of pins between the AC adapter and a load.

I claim:

1. A power system comprising:
a powered circuit to measure a voltage from an adjust pin associated with a power adapter, the voltage indicating a unique attribute of the power adapter; and
a controller to identify the unique attribute of the power adapter based on the voltage.

2. The power system of claim 1 wherein the controller is further to utilize a tablet to identify the unique attribute of the power adapter.

3. The power system of claim 1 wherein the powered circuit is further comprising an analog to digital converter (ADC) as input to the controller to receive the voltage from the adjust pin.

4. The power system of claim 1 wherein the power adapter is an alternating current (AC) adapter, the power system further comprising:
the AC adapter comprising:
the adjust pin to provide the voltage to the powered circuit, wherein the adjust pin adjusts an output voltage to the powered circuit; and
an output pin to provide the output voltage to the powered circuit; and
a connector to provide connections of the adjust pin, output pin, and a ground pin to the powered circuit.

5. The power system of claim 4 wherein the AC adapter is further comprising:
a resistor divider to provide the voltage to the powered circuit, wherein values of the resistor divider correspond to the voltage indicating the unique attribute of the AC adapter.

6. The power system of claim 4 wherein the unique attribute of the AC adapter is a unique power rating of the AC adapter and the AC adapter is further comprising:
a first resistor of fixed value;
a resistor divider including multiple resistors of various values to correspond to the voltage from the adjust pin, the voltage indicating the unique power rating of the AC adapter.

7. A non-transitory machine-readable storage medium encoded with instructions executable by a processor of a computing device, the storage medium comprising instructions to:
measure an adjust pin voltage, the adjust pin voltage indicating a unique attribute of an alternating current (AC) adapter; and
identify the unique attribute of the AC adapter corresponding to the adjust pin voltage.

8. The non-transitory machine-readable storage medium of claim 7 wherein the unique attribute is a unique power rating corresponding to the AC adapter, the storage medium is further comprising instructions to:
measure the adjust pin voltage from a voltage adjust pin which adjusts an output voltage of the AC adapter to a device;
process the adjust pin voltage according to a table to determine the power rating of the AC adapter.

9. The non-transitory machine-readable storage medium of claim 7 wherein for a series of AC adapters, each AC adapter including a different adjust pin voltage to identify a different unique power rating for each AC adapter.

10. The non-transitory machine-readable storage medium of claim 7 further comprising instructions to;
convert the adjust pin voltage to a digital signal for identifying the unique attribute of the AC adapter.

11. A method to identify a unique attribute of an alternating current (AC) adapter, the method comprising:
receiving an identifier, from a voltage adjust pin associated with the AC adapter, the identifier indicating a unique power rating of the AC adapter; and
identifying the unique power rating based on the received identifier by the voltage adjust pin.

12. The method of claim 11 wherein receiving the identifier from the voltage adjust pin is further comprising:
measuring, from the voltage adjust pin, a voltage which indicates the unique power rating of the AC adapter.

13. The method of claim 11 wherein identifying the power attribute of the AC adapter is further comprising:
utilizing a table to identify the unique power rating corresponding to the identifier.

14. The method of claim 11 wherein the identifier includes a unique voltage and further wherein for a series of AC adapters that share a common output voltage, each AC adapter includes a different identifying voltage at the voltage adjust pin indicating different unique power rating for each AC adapter.

15. The method of claim 11 further comprising:
converting the identifier to a digital identifier for identification of the unique power rating.
